(19) United States
(12) Patent Application Publication
(10) Pub. No.: US 2021/0345481 A1
(43) Pub. Date: Nov. 4, 2021

(54) INTEGRAL SUPER-CAPACITOR FOR LOW POWER APPLICATIONS

(71) Applicant: QUALCOMM Incorporated, San Diego, CA (US)

(72) Inventors: Mohit Kishore PRASAD, San Diego, CA (US); Lalan Jee MISHRA, San Diego, CA (US)

(21) Appl. No.: 16/862,130

(22) Filed: Apr. 29, 2020

(51) Int. Cl. H05K 1/02; H01G 4/018; H02J 7/00

(52) U.S. Cl. CPC H05K 1/0231; H02J 7/007; H01G 4/018

(57) ABSTRACT

Certain aspects of the present disclosure generally relate to an electronic device with a circuit board having one or more super-capacitors implemented therein using the layers of the circuit board. An example electronic device generally includes a circuit board having a capacitive element implemented therein, wherein the capacitive element comprises a first conductive layer, a second conductive layer disposed below the first conductive layer, and a solid dielectric material disposed between the first and second conductive layers, wherein the dielectric material has a high dielectric constant greater than 10,000 (1E4); and an integrated circuit coupled to the circuit board.

### BACKGROUND

### Field of the Disclosure

Certain aspects of the present disclosure generally relate to electronic components and, more particularly, to super-capacitors implemented within circuit boards.

### Description of Related Art

A continued emphasis in developing electronic devices is to create improved power efficiencies while the electronic device is powered via a battery (e.g., a lithium battery) or, in certain cases, via a capacitor. Lithium batteries are batteries that have metallic lithium as an anode. These types of batteries are also referred to as lithium-metal batteries. Lithium batteries stand apart from other batteries in their high charge density (long life) and high cost per unit.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include providing a super-capacitor implemented in a circuit board.

Certain aspects of the present disclosure provide an electronic device. The electronic device generally includes a circuit board having a capacitive element implemented therein and an integrated circuit coupled to the circuit board. The capacitive element generally includes a first conductive layer, a second conductive layer disposed below the first conductive layer, and a solid dielectric material disposed between the first and second conductive layers. The dielectric material has a high dielectric constant greater than 10,000 (1E4).

Certain aspects of the present disclosure provide a method for fabricating an electronic device. The method generally includes forming a circuit board having a capacitive element implemented therein and coupling an integrated circuit to the circuit board. The capacitive element generally includes a first conductive layer, a second conductive layer disposed above the first conductive layer, and a solid dielectric material disposed between the first and second conductive layers, wherein the dielectric material has a high dielectric constant greater than 10,000 (1E4).

Certain aspects of the present disclosure provide a method of using an electronic device. The method generally includes powering, with a capacitive element implemented in a circuit board, an integrated circuit coupled to the circuit board. The capacitive element generally includes a first conductive layer, a second conductive layer disposed below the first conductive layer, and a solid dielectric material disposed between the first and second conductive layers. The dielectric material has a high dielectric constant greater than 10,000 (1E4).

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1 is a cross-sectional view of an example electronic device having a circuit board with a capacitive element implemented therein, in accordance with certain aspects of the present disclosure.

FIG. 2 is a block diagram of an example electronic device, in accordance with certain aspects of the present disclosure.

FIGS. 3A-3D illustrate cross-sectional views of various circuit boards with capacitive elements implemented therein, in accordance with certain aspects of the present disclosure.

FIGS. 4A and 4B are tables representing example simulations of various capacitive elements implemented in a circuit board, in accordance with certain aspects of the present disclosure.

FIG. 5 is a flow diagram depicting example operations for fabricating an electronic device, in accordance with certain aspects of the present disclosure.

FIG. 6 is a flow diagram depicting example operations for using an electronic device, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure generally relate to a super-capacitive element implemented in a circuit board for energy storage in an electronic device, a method of using the electronic device, and a method of fabricating the electronic device.

A super-capacitor, also called an “ultracapacitor,” is a high-capacity capacitor with a capacitance value much higher than other capacitors, which may serve to bridge the gap between electrolytic capacitors and rechargeable batteries. Conventional techniques to include a super-capacitor with a printed circuit board (PCB) are costly and thus may not be suitable for certain applications, such as low-power applications or Internet-of-Things (IoT) devices. For example, the super-capacitor may have an aqueous or gel electrolyte disposed between a pair of electrodes, and, in such cases, the super-capacitor may be inserted after the PCB is fabricated. For example, the electrolyte may be injected into the PCB, and an upper electrode may be added, both after the PCB is initially constructed. The injection of the aqueous electrolyte poses great manufacturing challenges, drives up costs, and lowers overall reliability of the components.

Certain aspects of the present disclosure provide an electronic device having a capacitive element (e.g., a super-capacitor) with a solid dielectric material implemented in a circuit board. In certain aspects, the super-capacitor may provide power storage and supply power for the electronic device. Such an electronic device as further described herein may enable improved battery life, particularly for low-power applications. Some benefits of integrating a super-capacitor, having a solid dielectric, into the circuit board may include faster charge times than certain batteries (e.g., lithium batteries), more charge and discharge cycles than certain batteries, longer run cycles between charging, elimination of a lithium battery, and overall cost reduction in fabricating the electronic device.

In certain aspects, the circuit board may be multi-layered to allow for various electrical routing and/or additional capacitive elements implemented therein. The multiple layers in a circuit board may allow capacitors to be connected in parallel to increase the total capacitance, which increases the total charge storage. Alternatively, PCB stacking may be implemented to coordinate particular component placement, as well as to increase battery capacity. In certain aspects, the integral super-capacitors may be arranged in parallel (e.g., for higher current), series (e.g., for higher voltage), and parallel-series (e.g., for higher current and voltage). Additionally, piercing the electrodes of the super-capacitors in the circuit board may be avoided for maximizing, or at least increasing, the electrode area with the use of blind and/or buried vias, rather than through-hole vias.

In certain cases, a capacitive element may be coupled to a power management integrated circuit (PMIC) that can direct power to a load and/or integrated circuit of the electronic device. In certain aspects, the electronic device may have an energy harvester that recharges the capacitive element. As an example, the energy harvester may be an array of photodiodes in series and/or parallel combinations. In certain aspects, the energy harvester may include mechanical, kinetic, thermal, chemical, salinity gradient, solar, or any of various other suitable means for capturing and converting energy into electrical energy. In certain aspects, the PMIC may allow trickle-charging of a main battery when the energy harvester produces energy in excess of the storage capacity of the super-capacitor(s).

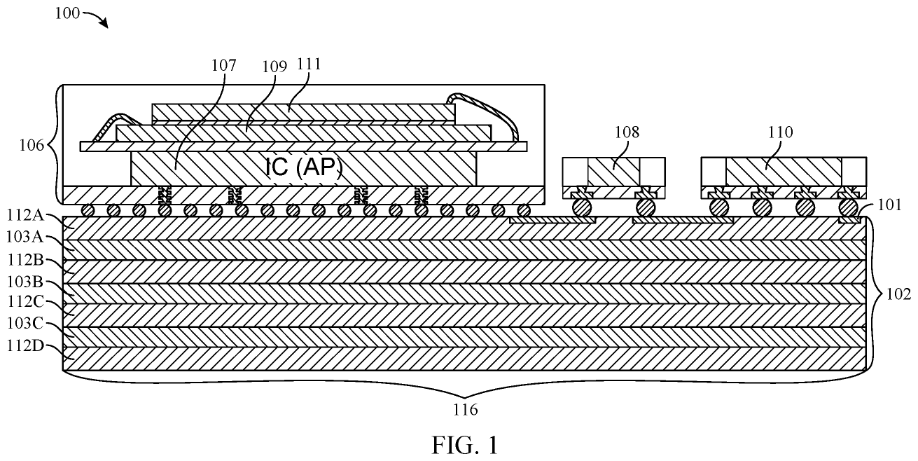

FIG. 1 depicts a cross-sectional view of an exemplary electronic device 100 having a super-capacitor implemented in a circuit board, in accordance with certain aspects of the present disclosure. As shown, the electronic device 100 may include a circuit board 102, a packaged assembly 106, which may include one or more integrated circuit (IC) dies 107, 109, 111, a power management integrated circuit (PMIC) 108, and an energy harvester 110. The electronic device 100 may be, for example, a low-power electronic device, such as an IoT device, a remote sensor (e.g., a field sensor), or wearable device (e.g., a smart watch).

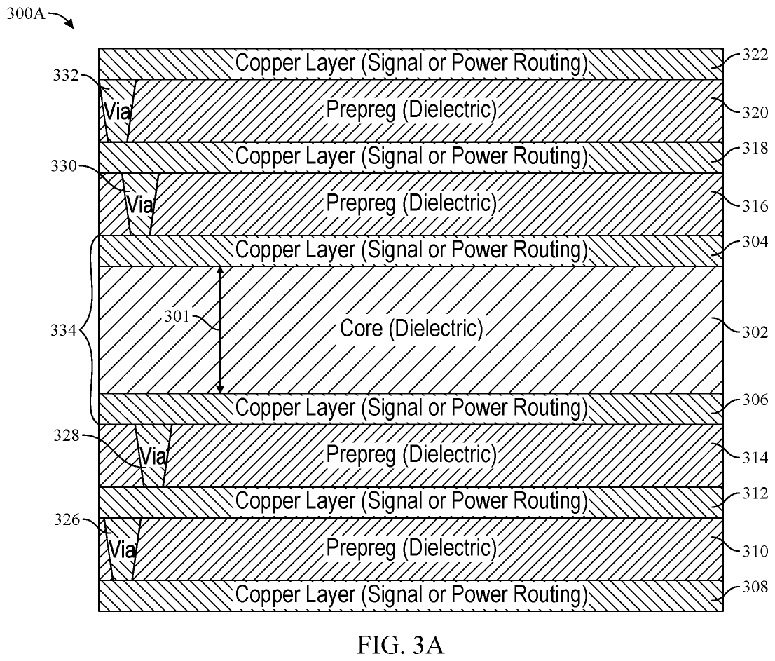

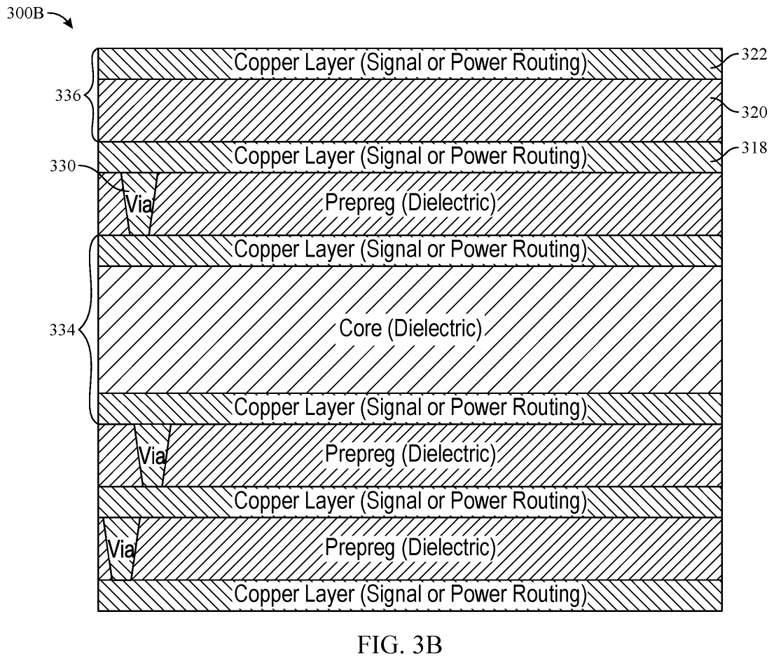

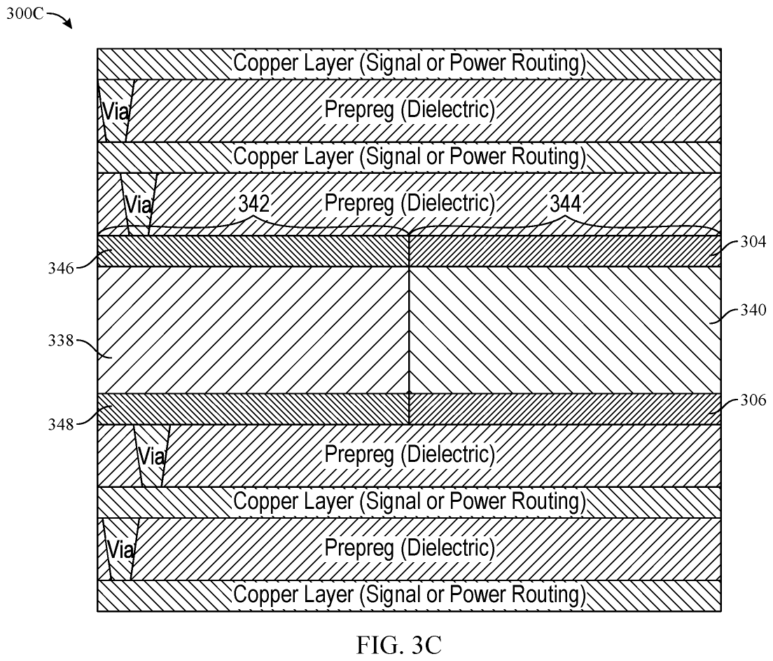

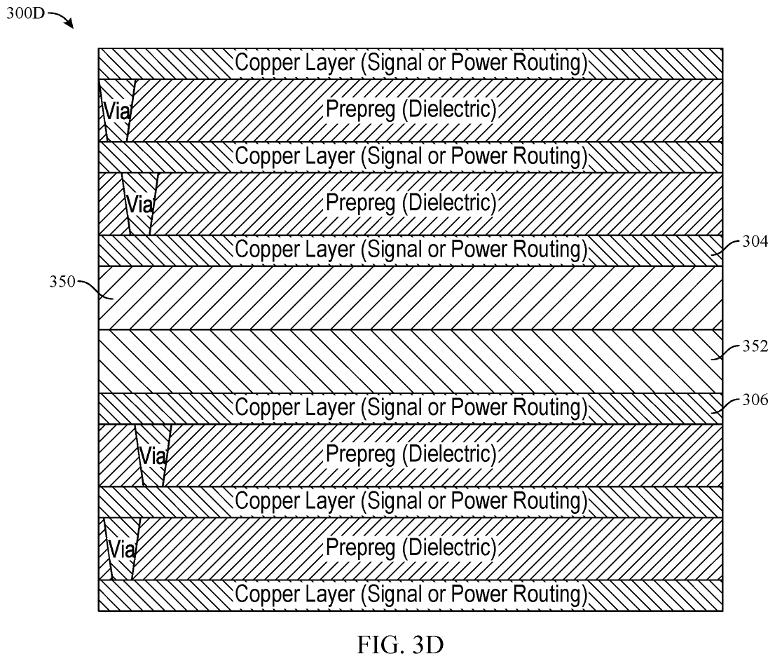

The circuit board 102 may be a PCB, motherboard, or any suitable carrier for electronic components such as the packaged assembly 106, PMIC 108, and/or energy harvester 110. The circuit board 102 may be composed of a polymer, an epoxy resin, or any other suitable material. The circuit board 102 may include various dielectric layers 103A, 103B, 103C (collectively referred to herein as “dielectric layers 103”) and conductive layers 112A, 112B, 112C, 112D (collectively referred to herein as “conductive layers 112”), as further described herein with respect to FIG. 3A. For example, the dielectric layers 103 may include layers of fiberglass impregnated with an epoxy resin (e.g., prepreg layers). The conductive layers 112 may include traces, planes, conductive pads, and/or other structures and may comprise any of various suitable materials for conducting electricity, such as metals or metal alloys, (e.g., Cu, Ag, Au, W, etc.). Although four conductive layers 112 and three dielectric layers 103 are illustrated in FIG. 1, it is to be understood that the circuit board may include more or less than these numbers of layers.

A super-capacitor may include a solid dielectric material disposed between two electrodes implemented in the circuit board 102, as further described herein with respect to FIG. 3A. For example, in FIG. 1, the combination of conductive layers 112B and 112C with dielectric layer 103B—where the dielectric layer 103B has a very high dielectric constant (e.g., εᵣ≥1E4), may form a super-capacitor contained within the electronic device 100. It is to be understood that the super-capacitor may be implemented on different layers of the circuit board or that multiple super-capacitors may be implemented within the circuit board, whether on the same or different layers. The super-capacitor may be electrically coupled to the packaged assembly 106 through vias and/or traces 101 of the circuit board 102. In certain aspects, the super-capacitor may span the entire length 116 and/or the entire width (extending into the page) of the circuit board 102. In other aspects, the super-capacitor may span a portion of the length 116 of the circuit board.

The packaged assembly 106 may include one or more IC dies 107, 109, 111. For example, IC die 107 may be a processor, whereas IC dies 109 and 111 may be memory devices (e.g., nonvolatile memory) coupled to the processor via an interposer, bond wires, and/or various other suitable means for electrically coupling two components. For example, the packaged assembly 106 may include a processor, a graphics processing unit (GPU), a digital signal processor (DSP), an application specific integrated circuit (ASIC), a field programmable gate array (FPGA) or other programmable logic device (PLD), discrete gate or transistor logic, or any combination thereof. In certain aspects, the packaged assembly 106 may be a system-on-a-chip (SoC) for a low-power electronic device. The packaged assembly 106 may be coupled to the circuit board 102, for example, via solder bumps or conductive pillars (e.g., copper pillars). In aspects, the packaged assembly 106 may be implemented in and perform the functions of memory, a motor controller, a handheld device, an IoT capable device, or the like.

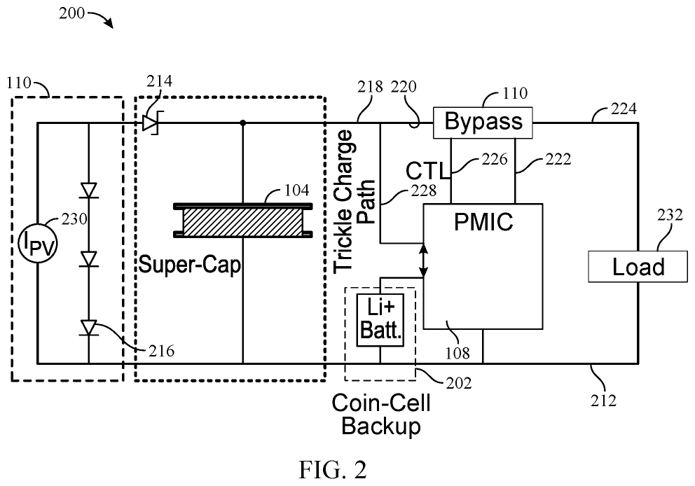

The PMIC 108 may include a power management circuit configured to supply power to the packaged assembly 106 via an electric charge stored by the super-capacitor implemented in the circuit board. For example, the PMIC 108 may be capable of DC-DC conversion (e.g., a low-dropout voltage regulator or a switched-mode power supply (SMPS), such as a buck converter), power sequencing, charging, power-source selection, or the like. The PMIC 108 may be coupled to the circuit board 102 and electrically coupled to the packaged assembly 106 and the super-capacitor (as shown in FIG. 2.) through other features of the circuit board (e.g., traces, planes, vias, and the like). The PMIC 108 may also be coupled to an optional backup battery (shown in FIG. 2) and/or to the energy harvester 110 (also optional).

The energy harvester 110 may include any suitable circuit for capturing energy from an energy source and generating an electric current therefrom, such as a mechanical energy harvester, kinetic energy harvester, thermal energy harvester, chemical energy harvester, salinity gradient energy harvester, solar energy harvester, or the like. For example, the energy harvester 110 may include a photovoltaic energy harvester configured to convert light for generating the electric current. As another example, the energy harvest 110 may be implemented as a radio-frequency (RF) energy harvester configured to convert electromagnetic radiation at certain radio frequencies (such as the millimeter wave bands of 5G New Radio (e.g., 24 GHz to 53 GHz)) for generating the electric current.

While the example electronic device depicted in FIG. 1 is described with respect to one or more integrated circuits being electrically coupled to and receiving power from the capacitive element to facilitate understanding, aspects of the present disclosure may also be applied to other electrical loads (e.g., a light-emitting device (e.g., a light-emitting diode (LED)), a memory device, a motor, a handheld device, a wearable electronic device, an IoT capable device, a sensor, or the like), additionally or alternatively, being electrically coupled to the capacitive element.

FIG. 2 is a block diagram of an example electronic circuit 200 for an electronic device (e.g., electronic device 100), in accordance with certain aspects of the present disclosure. In addition to the energy harvester 110, the capacitive element 104, and the PMIC 108, the electronic circuit 200 may further include a battery 202 and/or a bypass circuit 204. The load 232 may represent the packaged assembly 106 or other circuitry.

In certain aspects, the energy harvester 110 may be coupled between a diode 214 (e.g., a Schottky diode) and a reference node 212. The energy harvester 110 may include a photovoltaic energy harvester, a radio frequency (RF) energy harvester, or any other suitable circuit for generating an electric current, such as a mechanical energy harvester, kinetic energy harvester, thermal energy harvester, chemical energy harvester, salinity gradient energy harvester, solar energy harvester, or the like. Furthermore, the energy harvester 110 may comprise a set of one or more series-connected diodes 216 coupled in parallel with energy harvesting circuitry 230. In aspects, the set of diodes 216 may rectify the voltage signal output by the energy harvesting circuitry 230 and/or provide overvoltage protection for the rest of the electronic circuit 200. The diode 214 may prevent reverse current from the capacitive element 104 from flowing towards the energy harvester 110.

In certain aspects, the PMIC 108 may be coupled to a node 218 and the reference node 212. Furthermore, the PMIC 108 may be configured to control the bypass circuit 204 to direct power to the load 232.

The bypass circuit 204 may be configured to select a power source for delivering power to the load 232 and may be implemented as a switch. The bypass circuit 204 may include a first power input 220 coupled to node 218, a second power input 222, a power output 224, and a control input 226. The PMIC 108 may be coupled to the bypass circuit 204 via at least the second power input 222 and the control input 226. In a first state, the PMIC 108 may configure the bypass circuit 204 to allow the load 232 to be charged by the capacitive element 104 via the first power input 220. In a second state, the PMIC 108 may configure the bypass circuit 204 to allow the load 232 to be charged by the battery 202 via second power input 222 through the PMIC 108. In certain aspects, the PMIC 108 may have a DC-DC converter.

In addition to the capacitive element 104 for power, the battery 202 may provide a supplemental source of power. In aspects, the battery 202 may be trickle charged. In certain aspects, the trickle charging of the battery 202 may be managed by the PMIC 108. The capacitor may provide a charge through trickle charge line 228, and the PMIC 108 may direct the charge to the battery 202. In aspects, the battery 202 may be a coin cell backup battery. The load 232 may be coupled between the power output 224 of the bypass circuit 204 and the reference node 212.

FIG. 3A illustrates a cross-sectional view of an exemplary circuit board 300A (e.g., the circuit board 102) having a capacitive element implemented therein, in accordance with certain aspects of the present disclosure. The circuit board 300A includes a capacitive element 334, and the capacitive element 334 may include a first dielectric material 302, a first conductive layer 304, and a second conductive layer 306, which is disposed below the first conductive layer 304. A shown, the first dielectric material 302 is disposed between the first conductive layer 304 and the second conductive layer 306 to form a parallel-plate capacitor. In aspects, the first conductive layer 304 and the second conductive layer 306 may be separated from each other by a certain distance to provide a certain capacitance depending on the dielectric constant of the first dielectric material 302. For example, the first conductive layer 304 and second conductive layer 306 may be separated from each other by a distance 301 of 8 μm to 40 μm, or even less than 8 μm. In aspects, the conductive layers 304 and 306 may include various conductive materials (e.g., graphene), and/or various metal alloys or metals including aluminum (Al), chromium (Cr), cobalt (Co), copper (Cu), tantalum (Ta), titanium (Ti), tungsten (W), etc.

The first dielectric material 302 may be a solid dielectric material (e.g., a solid material without any aqueous or gel electrolyte) having a high dielectric constant, for example, greater than 10,000 (1E4). In aspects, the dielectric constant of the first dielectric material 302 may be in a range from 100,000,000 (1E8) to 1,000,000,000 (1E9). In certain aspects, the first dielectric material 302 may include a solid form of calcium copper titanate (CaCuTiO2) having a dielectric constant in the range from 100,000,000 (1E8) to 1,000,000,000 (1E9).

In certain aspects, the circuit board 300A may include additional dielectric layers and conductive layers for various electrical routing through the circuit board 300A. For example, the circuit board 300A may include a third conductive layer 308, a second dielectric layer 310 disposed above the third conductive layer 308, a fourth conductive layer 312 disposed above the second dielectric layer 310, a third dielectric layer 314 disposed above the fourth conductive layer 312 and below the conductive layer 306, a fifth conductive layer 318 disposed above a fourth dielectric layer 316 that is disposed above the conductive layer 304, and a sixth conductive layer 322 disposed above a fourth dielectric layer 320 that is disposed above the fifth conductive layer 318. In certain aspects, one or more of the dielectric layers (other than the portion(s) used to implement the super-capacitor(s)) may comprise prepreg. For example, the dielectric layer(s) may comprise fiberglass (FR4 fiber) impregnated with an epoxy resin.

In certain aspects, the various conductive layers may be electrically coupled to each other through conductive vias. For example, the circuit board 300A may include at least one first conductive via 326 to couple conductive layers 308, 312, at least one second conductive via 328 to couple conductive layers 312, 306, at least one third conductive via 330 to couple conductive layers 304, 318, and at least one fourth conductive via 332 to couple conductive layers 318, 322.

In certain aspects, the circuit board may include multiple capacitive elements implemented therein. For example, FIG. 3B illustrates a cross-sectional view of another exemplary circuit board 300B, in accordance with certain aspects of the present disclosure. With respect to the circuit board 300A of FIG. 3A, the circuit board 300B may be of similar construction, with the exception that the circuit board 300B may have an additional capacitive element 336 coupled in series with the capacitive element 334 through the at least one third conductive via 330. In certain cases, there may be no fourth conductive via 332 coupled between the conductive layers 318 and 322, which would short the two ends of the capacitive element 336. The fifth conductive layer 318, fourth dielectric layer 320, and sixth conductive layer 322 may form the capacitive element 336. In certain aspects, the capacitive element 336 may be a super-capacitor, while in other aspects the capacitive element may not be a super-capacitor. In other words, the capacitive element 336 may have a dielectric constant above or below 1E4.

FIG. 3C illustrates a cross-sectional view of an additional example of a circuit board 300C in accordance with certain aspects of the present disclosure. With respect to the circuit board 300A of FIG. 3A, the circuit board 300C may be of similar construction, with the exception that the circuit board 300C may have a first dielectric material 338 and a second dielectric material 340 disposed adjacent to one another. The first dielectric material 338 may be disposed between conductive layers 346 and 348 to form capacitive element 342. The second dielectric material 340 may be disposed between conductive layers 304 and 306 to form capacitive element 344. In certain aspects, the first dielectric material 338 may have a larger width and/or large length than the second dielectric material 340. In certain aspects, the first dielectric material 338 may have a smaller width and/or a smaller length than the second dielectric material 340. In certain aspects, the first dielectric material 338 may have an equal width (and/or equal length) in comparison with the second dielectric material 340. The capacitive element 342 and 344 of the circuit board 300C may be coupled in parallel.

FIG. 3D illustrates a cross-sectional view of an additional example of a circuit board 300D in accordance with certain aspects of the present disclosure. With respect to the circuit board 300A of FIG. 3A, the circuit board 300D may be of similar construction, with the exception that the circuit board 300D may have a first dielectric material 350 and a second dielectric material 352, both of which may be disposed between the first conductive layer 304 and the second conductive layer 306. The first dielectric material 350 may be disposed above the second dielectric material 352. Alternatively, the first dielectric material 350 may be disposed below the second dielectric material 352. The first dielectric material 350 may have a first dielectric constant, and the second dielectric material 352 may have a second dielectric constant. In certain aspects, the two dielectric constants of the two dielectric materials may be equal. In other aspects, the two dielectric constants of the two dielectric materials may be different. Furthermore, although two different dielectric layers are shown in FIG. 3D, certain aspects may include more than two dielectric layers in a capacitive element implemented therein.

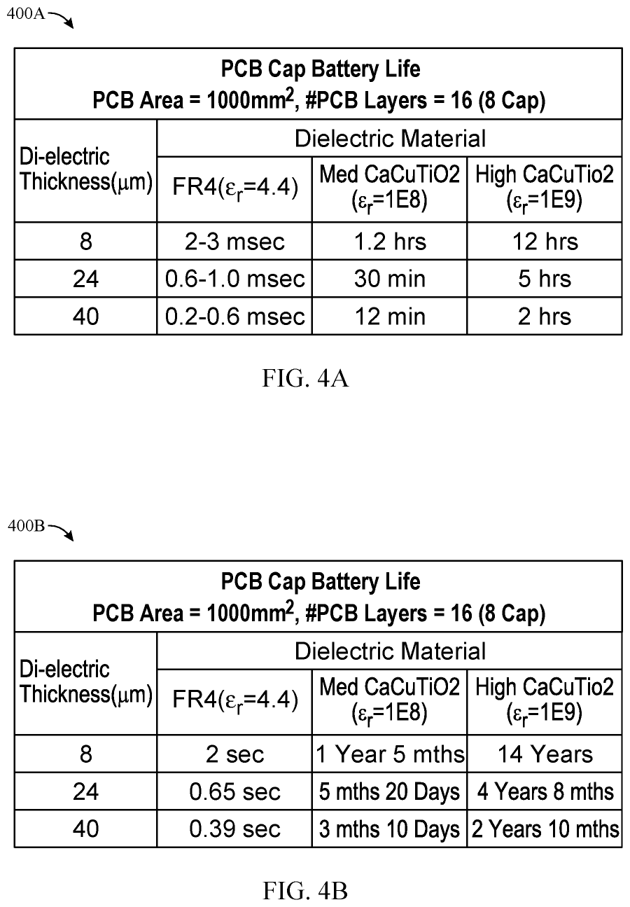

FIG. 4A is a table 400A representing simulation data of various example capacitive elements implemented in a circuit board, in accordance with certain aspects of the present disclosure. In the following examples, the circuit board has eight capacitive elements implemented therein, where the circuit board (and in this case, each of the electrodes in the capacitive elements) has an area of about 1000 mm². The table 400A represents how the distance between adjacent layers in the circuit board and the selection of the dielectric material affect the run time (i.e., the battery life) of each capacitive element. The simulation data in the table 400A represents the run times provided by the capacitive elements without energy harvesting.

For example, with a dielectric thickness of 8 μm for each of the capacitive elements in the circuit board, the capacitive elements having a dielectric material of glass-reinforced epoxy laminate material (e.g., FR4 with εᵣ=4.5) provide a run time of about 2-3 milliseconds (ms), the capacitive elements with a dielectric material of medium calcium copper titanate (CaCuTiO₂) (εᵣ=1E8) provide a run time of about 1.2 hours (hr), and the capacitive elements with a core of high CaCuTiO₂ (εᵣ=1E9) provide a run time of about 12 hr. With a dielectric thickness of 24 μm, the capacitive elements having a dielectric material of FR4 provide a run time of about 0.6-1.0 ms, the capacitive elements with a dielectric material of medium CaCuTiO₂ (εᵣ=1E8) provide a run time of about 30 minutes (min), and the capacitive elements with a dielectric material of high CaCuTiO₂ (εᵣ=1E9) provide a run time of about 5 hr. With a dielectric thickness of 40 μm, the capacitive elements with a dielectric material of FR4 offer a run time of about 0.2-0.6 ms, the capacitive elements with a dielectric material of medium CaCuTiO₂ (εᵣ=1E8) provide a run time of about 12 min, and the capacitive elements with a dielectric material of high CaCuTiO₂ (εᵣ=1E9) provide a run time of about 2 hr.

FIG. 4B is a table 400B representing simulation data of various example capacitive elements implemented in a circuit board, similar to the physical structure described above with respect to the table 400A of FIG. 4A, in accordance with certain aspects of the present disclosure. However, the simulation data in the table 400B represents the run times provided by the capacitive elements with energy harvesting.

With a dielectric thickness of 8 μm, the capacitive elements with a dielectric material of FR4 provide a run time of about 2 sec, capacitive elements with a dielectric material of medium CaCuTiO2 (εᵣ=1E8) provide a run time of about 1 year 5 months, and the capacitive elements with a dielectric material of high CaCuTiO2 (εᵣ=1E9) provide a run time of about 14 years. With a dielectric thickness of 24 μm, the capacitive elements with a dielectric material of FR4 provide a run time of about 0.65 seconds (s), the capacitive elements with a dielectric material of medium CaCuTiO2 (εᵣ=1E8) provide a run time of about 5 months 20 days, and the capacitive elements with a dielectric material of high CaCuTiO2 (εᵣ=1E9) provide a run time of about 4 year 8 months. With a dielectric thickness of 40 μm, the capacitive elements with a dielectric material of FR4 provide a run time of about 0.39 s, the capacitive elements with a dielectric material of medium CaCuTiO2 (εᵣ=1E8) provide a run time of about 3 months 10 days, and the capacitive elements with a dielectric material of high CaCuTiO2 (εᵣ=1E9) provide a run time of about 2 years 10 months.

The example capacitive elements as simulated in FIGS. 4A and 4B demonstrate that the high dielectric constant of high CaCuTiO₂ may enable the capacitive elements described herein to have dramatically improved run times, even without energy harvesting. Additionally, implementation of CaCuTiO₂ as a dielectric for an integral capacitive element may provide a viable alternative to lithium ion batteries and aqueous super-capacitors for prospective life span (e.g., recharging cycles) and/or improved cost of production.

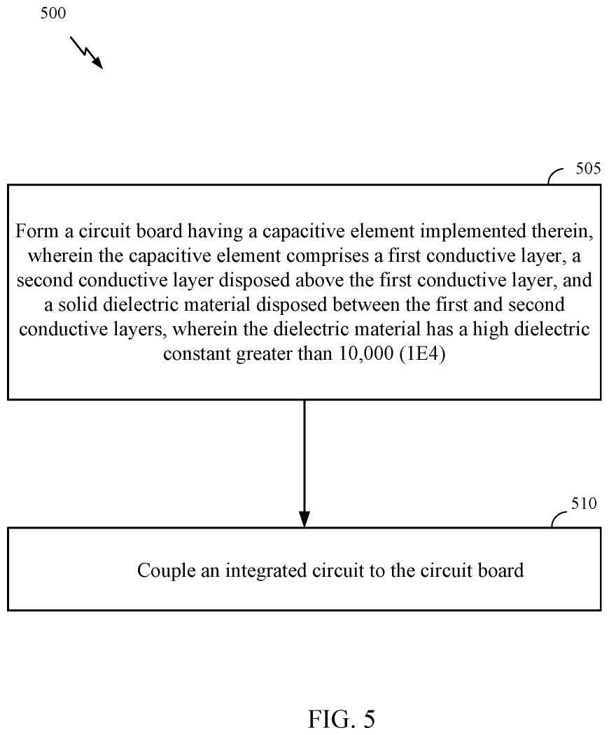

FIG. 5 is a block diagram of example operations 500 for fabricating an electronic device (e.g., the electronic device 100 depicted in FIG. 1), in accordance with certain aspects of the present disclosure. The operations 500 may be performed by an integrated circuit fabrication facility, for example.

The operations 500 begin at block 502 by forming a circuit board having a capacitive element (e.g., the capacitive element 104) implemented therein. In aspects, the capacitive element comprises a first conductive layer (e.g., the first conductive layer 304), a second conductive layer (e.g., the second conductive layer 306) disposed above the first conductive layer (e.g., the first conductive layer 304), and a solid dielectric material (e.g., the first dielectric material 302) disposed between the first and second conductive layers. In aspects, the dielectric material has a high dielectric constant greater than 10,000 (1E4). At block 504, an integrated circuit (e.g., the packaged assembly 106) may be coupled to the circuit board.

In certain aspects, the operations 500 may further include forming the dielectric material above the first conductive layer and forming the second conductive layer above the dielectric material. In certain aspects, the dielectric constant of the dielectric material ranges from 100,000,000 (1E8) to 1,000,000,000 (1E9). In certain cases, the dielectric material comprises calcium copper titanate (CaCuTiO₂).

In certain aspects, the operations 500 may further comprise forming additional capacitive elements (e.g., the capacitive element 336) above the capacitive element (e.g., the capacitive element 334), wherein each of the additional capacitive elements comprises a third conductive layer (e.g., fifth conductive layer 318), a fourth conductive layer (e.g., sixth conductive layer 322) disposed above the third conductive layer, and another dielectric material (e.g., fourth dielectric layer 320) disposed between the third conductive layer and the fourth conductive layer. Furthermore, forming the circuit board at block 502 may entail electrically coupling the capacitive elements in series with each other (e.g., FIG. 3B).

In certain aspects, the operations 500 may further comprise forming additional capacitive elements (e.g., capacitive element 344) disposed adjacent to the capacitive element (e.g., capacitive element 342), wherein each of the additional capacitive elements comprises a third conductive layer (e.g., the third conductive layer 348), a fourth conductive layer (e.g., the fourth conductive layer 346) disposed above the third conductive layer, and another dielectric material (e.g., dielectric material 338) disposed between the third conductive layer and the fourth conductive layer. In aspects, forming the circuit board at block 502 may include electrically coupling the capacitive elements in parallel with each other.

In certain aspects, the operations 500 may further comprise coupling an energy harvester (e.g., the energy harvester 110) to the circuit board. In this case, the energy harvester may be electrically coupled to the capacitive element through the circuit board and configured to generate an electric current for charging the capacitive element. In aspects, the energy harvester comprises a photovoltaic energy harvester configured to convert light for generating the electric current or a radio frequency (RF) energy harvester configured to convert electromagnetic radiation at radio frequencies for generating the electric current.

In certain aspects, the operations 500 may further comprise coupling a power management circuit (e.g., the PMIC 108) to the circuit board. In aspects, the power management circuit is electrically coupled to the integrated circuit and the capacitive element (e.g., capacitive element 104) through the circuit board. In aspects, the power management circuit is configured to supply power to the integrated circuit via an electric charge stored by the capacitive element.

In certain aspects, the operations 500 may further comprise coupling a battery (e.g., battery 202) to the circuit board. In this case, the battery may be electrically coupled to the power management circuit (e.g., PMIC 108).

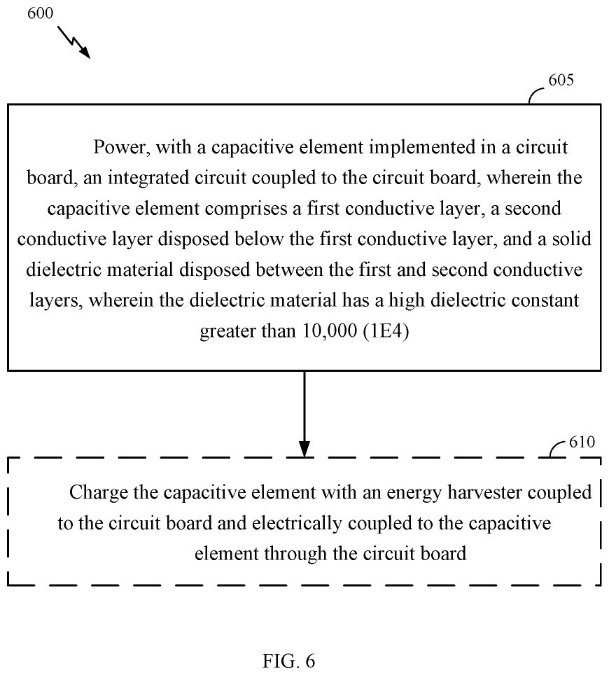

FIG. 6 is a block diagram of example operations 600 for using an electronic device (e.g., the electronic device 100 depicted in FIG. 1), in accordance with certain aspects of the present disclosure.

The operations 600 begin at block 602 by powering, with a capacitive element (e.g., capacitive element 104) implemented in a circuit board (e.g., the circuit board 102), an integrated circuit coupled to the circuit board, wherein the capacitive element comprises a first conductive layer (e.g., first conductive layer 304), a second conductive layer (e.g., second conductive layer 306) disposed below the first conductive layer, and a solid dielectric material (e.g., the first dielectric material 302) disposed between the first and second conductive layers, wherein the dielectric material has a high dielectric constant greater than 10,000 (1E4).

In certain aspects, the operations 600 may also include, at block 604, charging the capacitive element (e.g., capacitive element 104) with an energy harvester (e.g., energy harvester 110) coupled to the circuit board and electrically coupled to the capacitive element through the circuit board.

In certain aspects, the energy harvester (e.g., energy harvester 110) comprises a photovoltaic energy harvester configured to convert light for generating the electric current or a radio frequency (RF) energy harvester configured to convert electromagnetic radiation at radio frequencies for generating the electric current.

In certain aspects, powering the integrated circuit at block 602 comprises powering the integrated circuit via an electric charge stored by the capacitive element (e.g., capacitive element 104) through a power management circuit (e.g., the PMIC 108) coupled to the circuit board and electrically coupled to the integrated circuit and the capacitive element through the circuit board.

In certain aspects, the operations 600 may further comprise powering the integrated circuit via a battery (e.g., the battery 202) through the power management circuit. In certain aspects, operations 600 may further comprise controlling the capacitive element and a bypass switch (e.g., the bypass circuit 204) with a power management integrated circuit (PMIC) (e.g., the PMIC 108). The bypass switch may have a plurality of states. The PMIC may be configured to control the bypass switch. If a charge level of the capacitive element is above a threshold amount, the bypass switch may be configured into a first state. If a charge level of the capacitive element is at or below the threshold amount, the bypass switch may be configured into a second state. In certain aspects, during the first state, the capacitive element may charge a battery (e.g., battery 202). In other words, the bypass switch may be configured to power the IC with the capacitive element. However, the capacitive element may also trickle charge the battery.

In certain aspects, during the first state the capacitive element may also power the IC (e.g., the packaged assembly 106). For example, during the first state, the bypass switch may be configured to take input power from the capacitive element to deliver to the IC. In certain aspects, during the second state a battery powers the integrated circuit (e.g., the packaged assembly 106). For example, during the first state, the bypass switch may be configured to take input power from the battery to deliver to the IC. In certain aspects, during the second state the capacitive element is charged by an energy harvester (e.g., energy harvester 110). In certain aspects, during the second state the charge level of the capacitive element remains at or above an operating voltage of the integrated circuit.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes and variations may be made in the arrangement, operation and details of the methods and apparatus described above without departing from the scope of the claims.

1. An electronic device comprising:
a circuit board having a capacitive element implemented therein, wherein the capacitive element comprises a first conductive layer, a second conductive layer disposed below the first conductive layer, and a solid dielectric material disposed between the first and second conductive layers, wherein the dielectric material has a high dielectric constant greater than 10,000 (1E4); and
an integrated circuit coupled to the circuit board.

2. The device of claim 1, wherein the dielectric constant of the dielectric material is in a range from 100,000,000 (1E8) to 1,000,000,000 (1E9).

3. The device of claim 2, wherein the dielectric material comprises calcium copper titanate (CaCuTiO₂).

4. The device of claim 1, wherein the first and second conductive layers are separated from each other by a distance of less than 40 μm.

5. The device of claim 1, wherein the capacitive element spans at least one of an entire length or an entire width of the circuit board.

6. The device of claim 1, wherein:
the circuit board comprises one or more additional capacitive elements disposed above the capacitive element; and
each of the additional capacitive elements comprises a third conductive layer, a fourth conductive layer disposed above the third conductive layer, and another dielectric material disposed between the third conductive layer and the fourth conductive layer.

7. The device of claim 1, wherein:
the circuit board comprises one or more additional capacitive elements disposed adjacent to the capacitive element; and
each of the additional capacitive elements comprises a third conductive layer, a fourth conductive layer disposed above the third conductive layer, and another dielectric material disposed between the third conductive layer and the fourth conductive layer.

8. The device of claim 7, wherein the capacitive element and the one or more additional capacitive elements are electrically coupled in parallel with each other.

9. The device of claim 1, wherein the capacitive element comprises a plurality of dielectric layers disposed between the first and second conductive layers.

10. The device of claim 1, further comprising an energy harvester coupled to the circuit board and electrically coupled to the capacitive element through the circuit board, wherein the energy harvester is configured to generate an electric current for charging the capacitive element.

11. The device of claim 10, wherein the energy harvester comprises a photovoltaic energy harvester configured to convert light for generating the electric current or a radio frequency (RF) energy harvester configured to convert electromagnetic radiation at radio frequencies for generating the electric current.

12. The device of claim 10, further comprising a power management circuit coupled to the circuit board and electrically coupled to the integrated circuit and the capacitive element through the circuit board.

13. The device of claim 12, wherein the power management circuit is configured to supply power to the integrated circuit via an electric charge stored by the capacitive element.

14. The device of claim 12, further comprising a battery electrically coupled to the power management circuit.

15. A method of fabricating an electronic device, comprising:
forming a circuit board having a capacitive element implemented therein, wherein the capacitive element comprises a first conductive layer, a second conductive layer disposed above the first conductive layer, and a solid dielectric material disposed between the first and second conductive layers, wherein the dielectric material has a high dielectric constant greater than 10,000 (1E4); and
coupling an integrated circuit to the circuit board.

16. The method of claim 15, wherein forming the circuit board comprises:
forming the dielectric material above the first conductive layer; and
forming the second conductive layer above the dielectric material, wherein the dielectric constant of the dielectric material ranges from 100,000,000 (1E8) to 1,000,000,000 (1E9), and wherein the dielectric material comprises calcium copper titanate (CaCuTiO₂).

17. The method of claim 15, wherein forming the circuit board further comprises:
forming additional capacitive elements above the capacitive element, wherein each of the additional capacitive elements comprises a third conductive layer, a fourth conductive layer disposed above the third conductive layer, and another dielectric material disposed between the third conductive layer and the fourth conductive layer; and
electrically coupling the capacitive elements in series with each other.

18. The method of claim 15, wherein forming the circuit board further comprises:
forming additional capacitive elements disposed adjacent to the capacitive element, wherein each of the additional capacitive elements comprises a third conductive layer, a fourth conductive layer disposed above the third conductive layer, and another dielectric material disposed between the third conductive layer and the fourth conductive layer; and
electrically coupling the capacitive elements in parallel with each other.

19. The method of claim 15, further comprising coupling an energy harvester to the circuit board, wherein the energy harvester is electrically coupled to the capacitive element through the circuit board and configured to generate an electric current for charging the capacitive element.

20. The method of claim 19, wherein:
the energy harvester comprises a photovoltaic energy harvester configured to convert light for generating the electric current or a radio frequency (RF) energy harvester configured to convert electromagnetic radiation at radio frequencies for generating the electric current;
the method further comprises coupling a power management circuit to the circuit board;
the power management circuit is electrically coupled to the integrated circuit and the capacitive element through the circuit board; and
the power management circuit is configured to supply power to the integrated circuit via an electric charge stored by the capacitive element.
